(19) United States
(12) Patent Application Publication
(10) Pub. No.: US 2011/0227018 A1
(43) Pub. Date: Sep. 22, 2011

(54) MAGNETORESISTANCE ELEMENT, METHOD OF MANUFACTURING THE SAME, AND STORAGE MEDIUM USED IN THE MANUFACTURING METHOD

(75) Inventors: Masaki Kuribayashi, Tokyo (JP); David Djulianto Djayaprawira, Tokyo (JP)

(73) Assignee: CANON ANELVA CORPORATION, Kawasaki-shi, Kanagawa (JP)

(21) Appl. No.: 12/996,602

(22) PCT Filed: Aug. 12, 2009
(86) PCT No.: PCT/JP2009/003874

§ 371 Date: Jun. 8, 2011

(30) Foreign Application Priority Data
Sep. 8, 2008 (JP) 2008-229335

(51) Int. Cl. H01L 45/00; H01L 21/20

(52) U.S. Cl. 257/2; 438/3; 257/E45.002; 257/E21.09

(57) ABSTRACT

An embodiment of the invention provides a magnetoresistance element with an MR ratio higher than that of the related art and a method of manufacturing the same.

A magnetoresistance element includes a substrate, a first crystalline ferromagnetic layer, a tunnel barrier layer, a second crystalline ferromagnetic layer, a nonmagnetic intermediate layer, and a third crystalline ferromagnetic layer. The first ferromagnetic layer is made of an alloy containing Co atoms, Fe atoms, and B atoms. The tunnel barrier layer includes a crystalline magnesium oxide layer or a crystalline boron magnesium oxide layer. The second ferromagnetic layer is made of an alloy containing Co atoms and B atoms or an alloy containing Co atoms and Fe atoms. The third ferromagnetic layer is made of an alloy containing Ni atoms and Fe atoms.

### TECHNICAL FIELD

The present invention relates to a magnetoresistance element used in a magnetic reproducing head of a magnetic disk driving device, a storage element of a magnetic random access memory, and a magnetic sensor, and more particularly, to a tunneling magnetoresistance element (particularly, a spin-valve tunneling magnetoresistance element). In addition, the present invention relates a method of manufacturing a magnetoresistance element and a storage medium used in the manufacturing method.

### BACKGROUND ART

Patent Literatures 1 to 6 and Non-patent Literatures 1 and 2 disclose TMR (tunneling magnetoresistance) elements each having a tunnel barrier layer and first and second ferromagnetic layers that are provided on both sides of the tunnel barrier layer. The first and/or second ferromagnetic layers of the element are made of an alloy (hereinafter, a CoFeB alloy) containing Co atoms, Fe atoms, and B atoms. In addition, the CoFeB alloy layer has a polycrystalline structure.

Patent Literatures 2 to 5, Patent Literature 7, and Non-patent Literatures 1 to 5 disclose TMR elements which use a monocrystalline or polycrystalline magnesium oxide film as a tunnel barrier film.

### RELATED ART DOCUMENT

### Patent Literature

[Patent Literature 1] Japanese Patent Application Laid-Open (JP-A) No. 2002-204004
[Patent Literature 2] WO2005/088745
[Patent Literature 3] JP-A No. 2003-304010
[Patent Literature 4] JP-A No. 2006-080116
[Patent Literature 5] U.S. Patent Application Publication No. 2006/0056115
[Patent Literature 6] U.S. Pat. No. 7,252,852
[Patent Literature 7] JP-A No. 2003-318465

### Non-Patent Literature

[Non-patent Literature 1] D. D. Djayaprawira et al., ‘Applied Physics Letters’, 86, 092502 (2005)
[Non-patent Literature 2] Shinji Yuasa et al., ‘Japanese Journal of Applied Physics’, Vol. 43, No. 48, pp. 588-590, Published on Apr. 2, 2004
[Non-patent Literature 3] C. L. Platt et al., ‘J. Appl. Phys.’ 81(8), Apr. 15, 1997
[Non-patent Literature 4] W. H. Butler et al., ‘The American Physical Society’ (Physical Review Vol. 63, 054416) Jan. 8, 2001
[Non-patent Literature 5] S. P. Parkin et al., ‘2004 Nature Publishing Group’ Letters, pp. 862-887, Published on Oct. 31, 2004

### DISCLOSURE OF THE INVENTION

### Problem to be Solved by the Invention

An object of the invention is to provide a magnetoresistance element with an MR ratio higher than that of the related art, a method of manufacturing the same, and a storage medium used in the manufacturing method.

### Means for Solving the Problem

According to a first aspect of the invention, a magnetoresistance element includes: a substrate; a first crystalline ferromagnetic layer provided on the substrate and made of an alloy containing Co atoms, Fe atoms, and B atoms; a tunnel barrier layer provided on the first crystalline ferromagnetic layer and including a crystalline magnesium oxide layer or a crystalline boron magnesium oxide layer; a second crystalline ferromagnetic layer provided on the tunnel barrier layer and made of an alloy containing Co atoms, Fe atoms, and B atoms or an alloy containing Co atoms and Fe atoms; an intermediate layer that is provided on the second crystalline ferromagnetic layer and is made of a nonmagnetic material; and a third crystalline ferromagnetic layer provided on the intermediate layer and is made of an alloy containing Ni atoms and Fe atoms.

According to a second aspect of the invention, there is provided a method of manufacturing a magnetoresistance element. The method includes the steps of: preparing a substrate; forming a first ferromagnetic layer with an amorphous structure made of an alloy containing Co atoms, Fe atoms, and B atoms on the substrate using a sputtering method; forming a crystalline magnesium oxide layer or a crystalline boron magnesium oxide layer on the first ferromagnetic layer using the sputtering method; forming a second ferromagnetic layer with an amorphous structure made of an alloy containing Co atoms, Fe atoms, and B atoms or an alloy containing Co atoms and Fe atoms on the crystalline magnesium oxide layer or the crystalline boron magnesium oxide layer using the sputtering method; forming a nonmagnetic layer on the second ferromagnetic layer using the sputtering method; a step of forming a third ferromagnetic layer made of an alloy containing Ni atoms and Fe atoms on the nonmagnetic layer using the sputtering method; and crystallizing the first and second ferromagnetic layers with the amorphous structure.

According to a third aspect of the invention, there is provided a storage medium that stores a control program for manufacturing a magnetoresistance element using the steps of: preparing a substrate; forming a first ferromagnetic layer with an amorphous structure made of an alloy containing Co atoms, Fe atoms, and B atoms on the substrate using a sputtering method; forming a crystalline magnesium oxide layer or a crystalline boron magnesium oxide layer on the first ferromagnetic layer using the sputtering method; forming a second ferromagnetic layer with an amorphous structure made of an alloy containing Co atoms, Fe atoms, and B atoms or an alloy containing Co atoms and Fe atoms on the crystalline magnesium oxide layer or the crystalline boron magnesium oxide layer using the sputtering method; forming a nonmagnetic layer on the second ferromagnetic layer using the sputtering method; forming a third ferromagnetic layer made of an alloy containing Ni atoms and Fe atoms on the nonmagnetic layer using the sputtering method; and crystallizing the first and second ferromagnetic layers with the amorphous structure.

According to a fourth aspect of the invention, there is provided a method of manufacturing a magnetoresistance element. The method includes the steps of: preparing a substrate; forming a first ferromagnetic layer with an amorphous structure made of an alloy containing Co atoms, Fe atoms, and B atoms on the substrate using a sputtering method; forming a layer made of crystalline metal magnesium or a crystalline boron magnesium alloy on the first ferromagnetic layer using the sputtering method and oxidizing the metal magnesium or the boron magnesium alloy to form a crystalline magnesium oxide layer or a crystalline boron magnesium oxide layer; forming a second ferromagnetic layer with an amorphous structure made of an alloy containing Co atoms, Fe atoms, and B atoms or an alloy containing Co atoms and Fe atoms on the crystalline magnesium oxide layer or the crystalline boron magnesium oxide layer using the sputtering method; forming a nonmagnetic layer on the second ferromagnetic layer using the sputtering method; forming a third ferromagnetic layer made of an alloy containing Ni atoms and Fe atoms on the nonmagnetic layer using the sputtering method; and crystallizing the first and second ferromagnetic layers with the amorphous structure.

According to a fifth aspect of the invention, there is provided a storage medium that stores a control program for manufacturing a magnetoresistance element using the steps of: preparing a substrate; forming a first ferromagnetic layer with an amorphous structure made of an alloy containing Co atoms, Fe atoms, and B atoms on the substrate using a sputtering method; forming a layer made of crystalline metal magnesium or a crystalline boron magnesium alloy on the first ferromagnetic layer using the sputtering method and oxidizing the metal magnesium or the boron magnesium alloy to form a crystalline magnesium oxide layer or a crystalline boron magnesium oxide layer; forming a second ferromagnetic layer with an amorphous structure made of an alloy containing Co atoms, Fe atoms, and B atoms or an alloy containing Co atoms and Fe atoms on the crystalline magnesium oxide layer or the crystalline boron magnesium oxide layer using the sputtering method; forming a nonmagnetic layer on the second ferromagnetic layer using the sputtering method; forming a third ferromagnetic layer made of an alloy containing Ni atoms and Fe atoms on the nonmagnetic layer using the sputtering method; and crystallizing the first and second ferromagnetic layers with the amorphous structure.

### Effect of the Invention

According to an exemplary embodiment of the invention, it is possible to significantly improve the MR ratio of the tunneling magnetoresistance element (hereinafter, referred to as a TMR element) according to the related art. In addition, the invention can be mass-produced and has high practicality. Therefore, according to an exemplary embodiment of the invention, it is possible to provide a memory element of an ultra-large-scale integration MRAM (magnetoresistive random access memory: ferroelectric memory) with high efficiency.

### BRIEF DESCRIPTION OF THE DRAWINGS

FIG. 1 is a cross-sectional view schematically illustrating an example of a magnetoresistance element according to the invention.

FIG. 2 is a diagram schematically illustrating an example of the structure of a film forming apparatus that manufactures the magnetoresistance element according to the invention.

FIG. 3 is a block diagram illustrating the apparatus shown in FIG. 2.

FIG. 4 is a perspective view schematically illustrating an MRAM including the magnetoresistance element according to the invention.

FIG. 5 is an equivalent circuit diagram of the MRAM including the magnetoresistance element according to the invention.

FIG. 6 is a cross-sectional view illustrating another example of the tunnel barrier layer according to the invention.

FIG. 7 is a perspective view schematically illustrating the columnar crystal structure of the magnetoresistance element according to the invention.

FIG. 8 is a cross-sectional view illustrating another example of the TMR element of the magnetoresistance element according to the invention.

### BEST MODE FOR CARRYING OUT THE INVENTION

A magnetoresistance element according to an exemplary embodiment of the invention includes a substrate, a first crystalline ferromagnetic layer, a tunnel barrier layer, a second crystalline ferromagnetic layer, a nonmagnetic intermediate layer, and a third crystalline ferromagnetic layer. The first ferromagnetic layer is made of an alloy (hereinafter, referred to as CoFeB) containing Co atoms, Fe atoms, and B atoms. The tunnel barrier layer includes a crystalline magnesium oxide layer or a crystalline boron magnesium oxide layer. The second ferromagnetic layer is made of CoFeB or an alloy (hereinafter, referred to as CoFe) containing Co atoms and Fe atoms. The third ferromagnetic layer is made of an alloy (hereinafter, referred to as NiFe) containing Ni atoms and Fe atoms. In the following description, a magnesium oxide is referred to as a Mg oxide, a boron magnesium oxide is referred to as a BMg oxide, metal magnesium is referred to as Mg, and a boron magnesium alloy is referred to as BMg.

Hereinafter, exemplary embodiments of the invention will be described in detail.

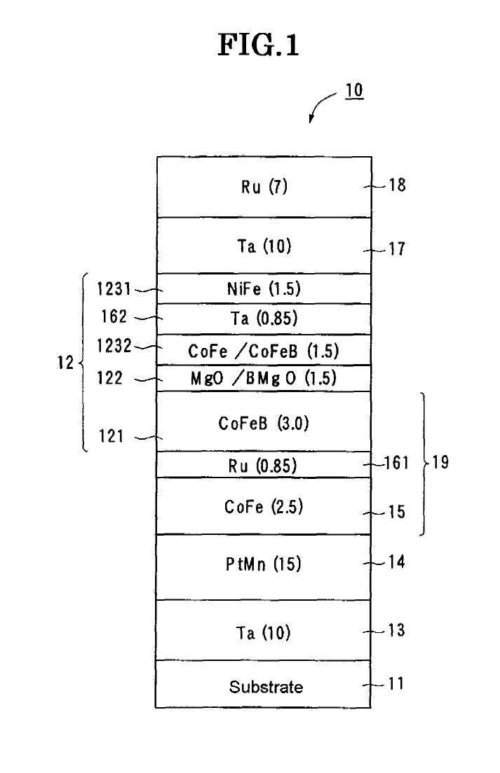

FIG. 1 is a diagram illustrating an example of the laminated structure of a magnetoresistance element 10 including a TMR element 12 according to an exemplary embodiment of the invention. The magnetoresistance element 10 includes, for example, a multi-layer film of eleven layers containing the TMR element 12 formed on a substrate 11. The eleven layers form a multi-layer film structure from a first layer (Ta layer), which is the lowest layer, to an eleventh layer (Ru layer), which is the uppermost layer. Specifically, a PtMn layer 14, a CoFe layer 15, a nonmagnetic metal layer (Ru layer) 161, a CoFeB layer 121, which is the first ferromagnetic layer, and a nonmagnetic polycrystalline Mg or BMg oxide layer 122, which is the tunnel barrier layer. In addition, a polycrystalline CoFe or CoFeB layer 1232, which is the second ferromagnetic layer, a nonmagnetic Ta layer 162, a polycrystalline NiFe layer 1231, which is the third ferromagnetic layer, a nonmagnetic Ta layer 17, and a nonmagnetic Ru layer 18 are formed thereon in this order. In this way, magnetic layers and nonmagnetic layers are formed. In FIG. 1, a numeric value in parentheses of each layer indicates the thickness of the layer and the unit thereof is nanometer. The thickness of each layer is just an illustrative example, and the invention is not limited thereto.

In an exemplary embodiment of the invention, the first ferromagnetic layer may have a laminated structure of two or more layers including the CoFeB layer 121 and other ferromagnetic layers.

Reference numeral 11 denotes a substrate, such as a wafer substrate, a glass substrate, or a sapphire substrate.

Reference numeral 12 denotes a TMR element which is a laminated structure of the first ferromagnetic layer 121 made of polycrystalline CoFeB, the tunnel barrier layer 122, the second ferromagnetic layer 1232, and the third ferromagnetic layer 1231. The tunnel barrier layer 122 has a polycrystalline Mg oxide layer or a polycrystalline BMg oxide layer. The second ferromagnetic layer 1232 is a polycrystalline CoFe layer or a polycrystalline CoFeB layer. The third ferromagnetic layer 1231 is a polycrystalline NiFe layer.

An intermediate layer 162 made of a nonmagnetic material is provided between the second ferromagnetic layer 1232, which is a polycrystalline CoFe layer or a polycrystalline CoFeB layer, and the third ferromagnetic layer 1231, which is a polycrystalline NiFe layer.

According to an exemplary embodiment of the invention, the polycrystalline NiFe forming the third ferromagnetic layer may contain a very small amount of other atoms, such as B, Co, and Pt atoms (5 atomic % or less, preferably, in the range of 0.01 atomic % to 1 atomic %).

Reference numeral 13 denotes a lower electrode layer (base layer), which is the first layer (Ta layer), and reference numeral 14 denotes an antiferromagnetic layer, which is the second layer (PtMn layer). Reference numeral 15 denotes a ferromagnetic layer, which is the third layer (CoFe layer), and reference numeral 161 denotes a nonmagnetic layer for exchange coupling, which is the fourth layer (Ru layer).

The fifth layer is a ferromagnetic layer, which is the crystalline CoFeB layer 121. The content of B atoms (hereinafter, referred to as the content of B) in the crystalline CoFeB layer 121 is preferably in the range of 0.1 atomic % to 60 atomic %, more preferably, in the range of 10 atomic % to 50 atomic %.

In an exemplary embodiment of the invention, the crystalline CoFeB layer 121 may contain a very small amount of other atoms, such as Pt, Ni, and Mn atoms (5 atomic % or less, preferably, in the range of 0.01 atomic % to 1 atomic %).

The third layer, the fourth layer, and the fifth layer form a magnetization fixed layer 19. The substantial magnetization fixed layer 19 is the ferromagnetic layer, which is the fifth crystalline CoFeB layer 121.

Reference numeral 122 denotes a tunnel barrier layer, which is the sixth layer (a polycrystalline Mg oxide layer or a polycrystalline BMg oxide layer), and the tunnel barrier layer is an insulating layer. The tunnel barrier layer 122 may be a single polycrystalline Mg oxide layer or a single polycrystalline BMg oxide layer.

The tunnel barrier layer 122 according to an exemplary embodiment of the invention may have the structure shown in FIG. 6. That is, the tunnel barrier layer 122 has a laminated structure of a polycrystalline Mg or BMg oxide layer 1221, a polycrystalline Mg or BMg layer 1222, and a polycrystalline Mg or BMg oxide layer 1223. In addition, the tunnel barrier layer 122 may have a laminated structure of a plurality of multi-layer films each including three layers, that is, the layers 1221, 1222, and 1223 shown in FIG. 6.

FIG. 8 is a diagram illustrating another example of the TMR element 12 according to an exemplary embodiment of the invention. In FIG. 8, reference numerals 12, 121, 122, 162, 1231, and 1232 denote the same members as described above. In this example, the tunnel barrier layer 122 is a laminated film of a polycrystalline Mg or BMg oxide layer 82 and Mg or BMg layers 81 and 83 that are provided on both sides of the layer 82. In an exemplary embodiment of the invention, the layer 81 may be omitted and the layer 82 may be arranged adjacent to the crystalline CoFe or CoFeB layer 1232. Alternatively, the layer 83 may be omitted and the layer 82 may be arranged adjacent to the crystalline CoFeB layer 121.

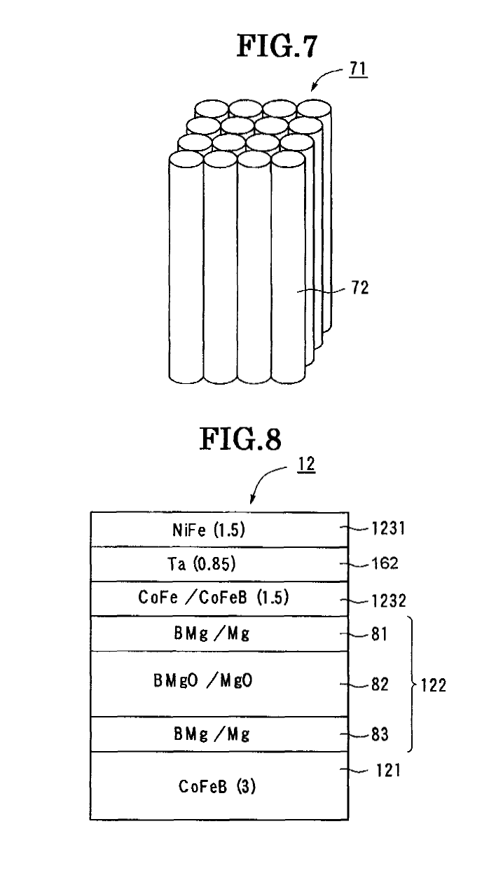

FIG. 7 is a perspective view schematically illustrating a polycrystalline structure including an aggregate 71 of columnar crystals 72 in the BMg oxide layer or the Mg oxide layer. The polycrystalline structure also includes a structure of a polycrystalline-amorphous mixture region having a partial amorphous region in a polycrystalline region. It is preferable that each columnar crystal be a single crystal in which the (001) crystal plane is preferentially arranged in the thickness direction. The average diameter of the columnar single crystals is preferably 10 nm or less, more preferably, in the range of 2 nm to 5 nm. The thickness of the columnar single crystal is preferably 10 nm or less, more preferably, in the range of 0.5 nm to 5 nm.

The BMg oxide used in an exemplary embodiment of the invention is represented by the following formula:

BₓMg_{y}O_{z}(0.7≦Z/(X+Y)≦1.3, preferably, 0.8≦Z/(X+Y)<1.0).

In an exemplary embodiment of the invention, it is preferable to use a stoichiometric amount of BMg oxide. However, an oxygen-defective BMg oxide may be used to obtain a high MR ratio.

The Mg oxide used in an exemplary embodiment of the invention is represented by the following formula:

Mg_{y}O_{z}(0.7≦Z/Y≦1.3, preferably, 0.8≦Z/Y<1.0).

In an exemplary embodiment of the invention, it is preferable to use a stoichiometric amount of Mg oxide. However, an oxygen-defective Mg oxide may be used to obtain a high MR ratio.

The polycrystalline Mg oxide or the polycrystalline BMg oxide used in an exemplary embodiment of the invention may contain various kinds of minor components. For example, the polycrystalline Mg oxide or the polycrystalline BMg oxide may contain 10 ppm to 100 ppm of Zn atoms, C atoms, Al atoms, Ca atom, and Si atoms.

The seventh layer is the crystalline CoFe or CoFeB layer 1232, which is the second ferromagnetic layer, and the ninth layer is the crystalline NiFe layer 1231, which is the third ferromagnetic layer, respectively. A laminated film including the seventh layer and the ninth layer may function as a magnetization free layer.

In an exemplary embodiment of the invention, the Ta layer 162 as the eighth layer, which is an intermediate layer made of a nonmagnetic material, is provided between the seventh layer and the ninth layer. The eighth layer may be made of a nonmagnetic metal material, such as Ru or Ir, or a nonmagnetic insulating material, such as Al₂O₃ (aluminum oxide), SiO₂ (silicon oxide), or Si₃N₄ (silicon nitride), in addition to Ta. The thickness of the eighth layer is preferably 50 nm or less, more preferably, in the range of 5 nm to 40 nm.

The crystalline CoFe or CoFeB layer 1232, which is the seventh layer, may be formed by a sputtering method using a CoFe target or a CoFeB target. The crystalline NiFe layer 1231, which is the ninth layer, may be formed by a sputtering method using a NiFe target.

The crystalline CoFeB layer 121, the CoFe or CoFeB layer 1232, and the NiFe layer 1231 may have the same crystal structure as that including the aggregate 71 of the columnar crystals 72 shown in FIG. 7.

It is preferable that the crystalline CoFeB layer 121 and the CoFe or CoFeB layer 1232 be provided adjacent to the tunnel barrier layer 122 arranged therebetween. The three layers are sequentially laminated in a manufacturing apparatus without breaking vacuum.

Reference numeral 17 denotes an electrode layer, which is the tenth layer (Ta layer).

Reference numeral 18 denotes a hard mask layer, which is the eleventh layer (Ru layer). When the eleventh layer is used as a hard mask, it may be removed from the magnetoresistance element.

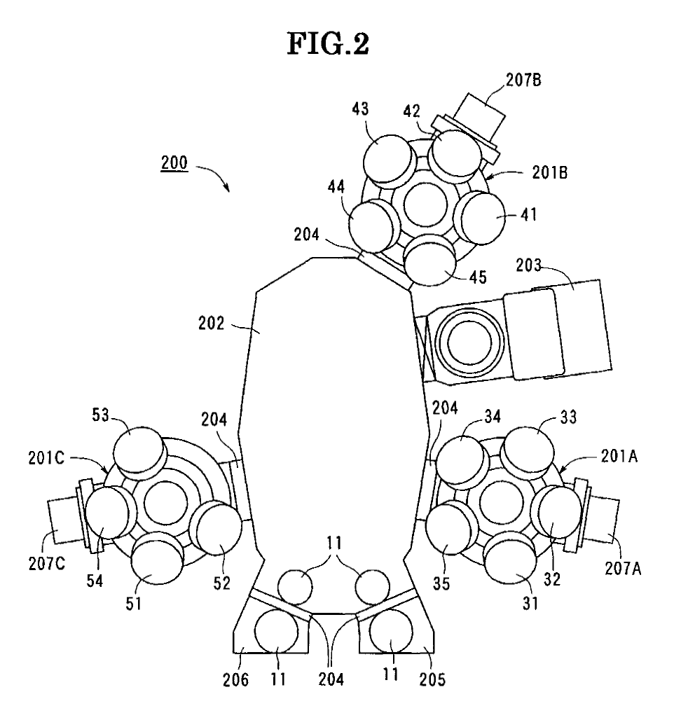

Next, a method and apparatus for manufacturing the magnetoresistance element 10 having the above-mentioned laminated structure will be described with reference to FIG. 2. FIG. 2 is a plan view schematically illustrating an apparatus for manufacturing the magnetoresistance element 10. The apparatus is a sputtering apparatus for mass production that is capable of manufacturing a multi-layer film including a plurality of magnetic layers and nonmagnetic layers.

A magnetic multi-layer film manufacturing apparatus 200 shown in FIG. 2 is a cluster-type manufacturing apparatus and includes three film forming chambers based on a sputtering method. In the apparatus 200, a transport chamber 202 having a robot transport apparatus (not shown) is provided at the center. The transport chamber 202 of the manufacturing apparatus 200 for manufacturing the magnetoresistance element is provided with two load lock and unload lock chambers 205 and 206 by which the substrate (for example, a silicon substrate) 11 is carried in and out. It is possible to reduce the tact time and manufacture a magnetoresistance element with high yield by alternately carrying the substrate in or out from the transport chamber using the load lock and unload lock chambers 205 and 206.

In the manufacturing apparatus 200 for manufacturing the magnetoresistance element, three film-forming magnetron sputtering chambers 201A to 201C and one etching chamber 203 are provided around the transport chamber 202. The etching chamber 203 etches a predetermined surface of the TMR element 10. Gate valves 204 are openably provided between the transport chamber 202 and the chambers 201A to 201C and 203. Each of the chambers 201A to 201C and 202 is provided with, for example, an evacuation mechanism, a gas introduction mechanism, and a power supply mechanism (not shown). The film-forming magnetron sputtering chambers 201A to 2010 can sequentially deposit the first to eleventh layers on the substrate 11 using a radio frequency sputtering method, without breaking vacuum.

Five cathodes 31 to 35, five cathodes 41 to 45, and four cathodes 51 to 54 are arranged on appropriate circumferences of the ceilings of the film-forming magnetron sputtering chambers 201A to 201C, respectively. The substrate 11 is arranged on a substrate holder that is provided coaxially with the circumference. It is preferable to use a magnetron sputtering apparatus in which magnets are arranged on the rear surfaces of targets mounted on the cathodes 31 to 35, the cathodes 41 to 45, and the cathodes 51 to 54.

In the apparatus, power supply units 207A to 207C apply high-frequency power, such as radio frequency power (RF power), to the cathodes 31 to 35, the cathodes 41 to 45, and the cathodes 51 to 54, respectively. As the radio frequency power, a frequency of 0.3 MHz to 10 GHz, preferably, 5 MHz to 5 GHz, and a power of 10 W to 500 W, preferably, 100 W to 300 W may be used.

In the above-mentioned structure, for example, a Ta target is mounted on the cathode 31, a PtMn target is mounted on the cathode 32, a CoFeB target is mounted on the cathode 33, a CoFe target is mounted on the cathode 34, and a Ru target is mounted on the cathode 35.

In addition, a Mg oxide target is mounted on the cathode 41, a BMg oxide target is mounted on the cathode 42, a Mg target is mounted on the cathode 43, and a BMg target is mounted on the cathode 44. The tunnel barrier layer 122 having the structure shown in FIG. 8 may be formed using the cathode 43 or 44. No target may be mounted on the cathode 45.

A NiFe target for the ninth layer is mounted on the cathode 51, and a CoFeB target for the seventh layer is mounted on the cathode 52. In addition, a Ru target for the eleventh layer is mounted on the cathode 53, and a Ta target for the eighth and tenth layers is mounted on the cathode 54.

It is preferable that the in-plane direction of each of the targets mounted on the cathodes 31 to 35, the cathodes 41 to 45, and the cathodes 51 to 54 be not parallel to the in-plane direction of the substrate. When the non-parallel arrangement is used, it is possible to effectively deposit a magnetic film and a nonmagnetic film with the same composition as a target composition by performing sputtering while rotating a target with a diameter smaller than that of the substrate.

As an example of the non-parallel arrangement, the central axis of the target and the central axis of the substrate may be arranged so as to intersect each other at an angle of 45° or less, preferably, at an angle of 5° to 30°. In this case, the substrate may be rotated at a speed of 10 rpm to 500 rpm, preferably, at a speed of 50 rpm to 200 rpm.

The crystalline Mg oxide layer may be obtained by forming a crystalline (preferably, polycrystalline) Mg layer by a sputtering method using a Mg target and introducing an oxidizing gas into an oxidation chamber (not shown) to oxidize Mg.

The crystalline BMg oxide layer may be obtained by forming a crystalline (preferably, polycrystalline) BMg layer by a sputtering method using a BMg target and introducing an oxidizing gas into the oxidation chamber (not shown) to oxidize BMg.

For example, an oxygen gas, an ozone gas, or vapor may be used as the oxidizing gas.

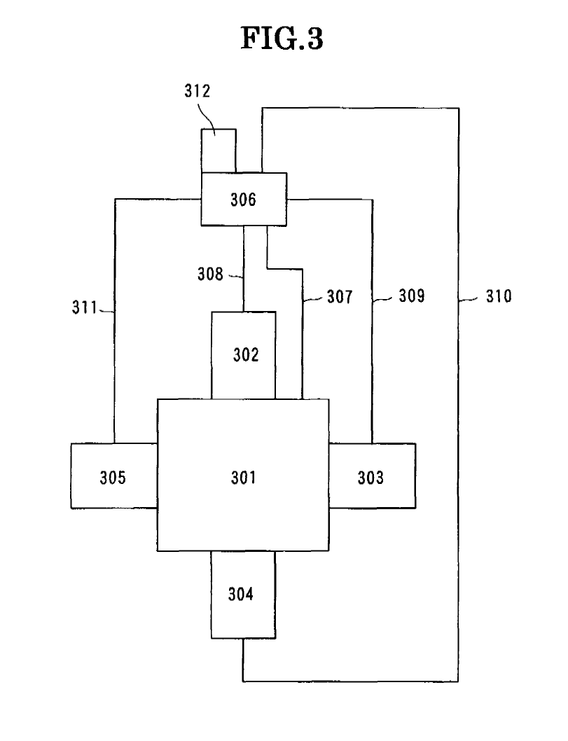

FIG. 3 is a block diagram illustrating the film forming apparatus according to an exemplary embodiment of the invention. In FIG. 3, reference numeral 301 denotes a transport chamber corresponding to the transport chamber 202 shown in FIG. 2, reference numeral 302 denotes a film forming chamber corresponding to the film-forming magnetron sputtering chamber 201A, and reference numeral 303 denotes a film forming chamber corresponding to the film-forming magnetron sputtering chamber 201B. In addition, reference numeral 304 denotes a film forming chamber corresponding to the film-forming magnetron sputtering chamber 201C, and reference numeral 305 denotes a load lock and unload lock chamber corresponding to the load lock and unload lock chambers 205 and 206. Reference numeral 306 denotes a central processing unit (CPU) embedded with a storage medium 312. Reference numerals 309 to 311 denote bus lines which connect the CPU 306 and the process chambers 301 to 305 and through which control signals for controlling the operations of the process chambers 301 to 305 are transmitted from the CPU 306 to the process chambers 301 to 305.

In an exemplary embodiment of the invention, the substrate (not shown) in the load lock and unload lock chamber 305 is carried out into the transport chamber 301. The step of carrying out the substrate is calculated by the CPU 306 based on the control program stored in the storage medium 312. The control signals based on the calculation result are transmitted through the bus lines 307 and 311 to control the operations of various apparatuses in the load lock and unload lock chamber 305 and the transport chamber 301. Various apparatuses include, for example, a gate valve, a robot mechanism, a transport mechanism, and a driving system (not shown).

The substrate transported to the transport chamber 301 is carried out into the film forming chamber 302. The first layer (Ta layer 13), the second layer (PtMn layer 14), the third layer (CoFe layer 15), the fourth layer (Ru layer 161), and the fifth layer (CoFeB layer 121) shown in FIG. 1 are sequentially formed on the substrate carried into the film forming chamber 302. In this stage, preferably, the CoFeB layer 121, which is the fifth layer, has an amorphous structure. However, the CoFeB layer 121 may have a polycrystalline structure.

The formation of the layers is performed by transmitting the control signal which is calculated by the CPU 306 based on the control program stored in the storage medium 312 to various apparatuses mounted in the transport chamber 301 and the film forming chamber 302 through the bus lines 307 and 308 to control the operations of the apparatuses. Various apparatuses include, for example, a power supply mechanism that supplies power to the cathodes, a substrate rotating mechanism, a gas introduction mechanism, an exhaust mechanism, a gate valve, a robot mechanism, a transport mechanism, and a driving system, which are not shown in the drawings.

The substrate having the first to fifth layers formed thereon returns to the transport chamber 301 and is then carried into the film forming chamber 303.

In the film forming chamber 303, the polycrystalline Mg or BMg oxide layer 122 is formed as the sixth layer on the amorphous CoFeB layer 121, which is the fifth layer. The formation of the sixth layer is performed by transmitting the control signal which is calculated by the CPU 306 based on the control program stored in the storage medium 312 to various apparatuses mounted in the transport chamber 301 and the film forming chamber 303 through the bus lines 307 and 309 to control the operations of the apparatuses. Various apparatuses include, for example, a power supply mechanism that supplies power to the cathodes, a substrate rotating mechanism, a gas introduction mechanism, an exhaust mechanism, a gate valve, a robot mechanism, a transport mechanism, and a driving system, which are not shown in the drawings.

The substrate having the first layer to the polycrystalline Mg or BMg oxide layer 122, which is the sixth layer, formed thereon returns to the transport chamber 301 and is then carried into the film forming chamber 304.

In the film forming chamber 304, the seventh layer (CoFe or CoFeB layer 1232), the eighth layer (Ta layer 162), the ninth layer (NiFe layer 1231), the tenth layer (Ta layer 17), and the eleventh layer (Ru layer 18) are sequentially formed on the sixth layer 122. In this stage, it is preferable that the CoFe or CoFeB layer 1232, which is the seventh layer, and the NiFe layer 1231, which is the ninth layer, have an amorphous structure. However, they may have a polycrystalline structure.

The formation of the layers is performed by transmitting the control signal which is calculated by the CPU 306 based on the control program stored in the storage medium 312 to various apparatuses mounted in the transport chamber 301 and the film forming chamber 304 through the bus lines 307 and 310 to control the operations of the various types of apparatuses. Various apparatuses include, for example, a power supply mechanism that supplies power to the cathodes, a substrate rotating mechanism, a gas introduction mechanism, an exhaust mechanism, a gate valve, a robot mechanism, a transport mechanism, and a driving system, which are not shown in the drawings.

The Ta layer 162, which is the eighth layer, and the Ta layer 17, which is the tenth layer, are formed using the same target mounted on the cathode 54.

The storage medium 312 corresponds to the storage medium according to an exemplary embodiment of the invention and stores a control program for manufacturing the magnetoresistance element.

Any kind of media capable of storing the program may be used as the storage medium 312 used in the invention. For example, a nonvolatile memory, such as a hard disk medium, a magneto-optical disk medium, a floppy (registered trademark) disk medium, a flash memory, or an MRAM, may be used as the storage medium.

According to an exemplary embodiment of the invention, it is possible to crystallize the fifth layer (CoFeB layer 121), the seventh layer (CoFe or CoFeB layer 1232), and the ninth layer (NiFe layer 1231) in an amorphous state immediately after being formed using an annealing process such that the layers have the polycrystalline structure shown in FIG. 7. Therefore, in an exemplary embodiment of the invention, it is possible to carry the formed magnetoresistance element 10 into an annealing furnace (not shown) and perform annealing to change the phase of each of the fifth layer 121, the seventh layer 1232, and the ninth layer 1231 from an amorphous state to a crystalline state.

In this case, it is possible to magnetize the PtMn layer 14, as the second layer.

A control program for performing the step in the annealing furnace is stored in the storage medium 312. Therefore, it is possible to control various apparatuses (for example, a heater mechanism, an exhaust mechanism, and a transport mechanism) in the annealing furnace based on the control signal, which is obtained by the CPU 306 based on the control program, thereby performing the annealing step.

In an exemplary embodiment of the invention, a Rh layer or an Ir layer may be used, instead of the Ru layer, as the fourth layer 161.

In an exemplary embodiment of the invention, it is preferable to use an alloy layer, such as an IrMn layer, an IrMnCr layer, a NiMn layer, a PdPtMn layer, a RuRhMn layer, or an OsMn layer, as the PtMn layer 14, which is the second layer. In addition, it is preferable that the thickness thereof be in the range of 10 nm to 30 nm.

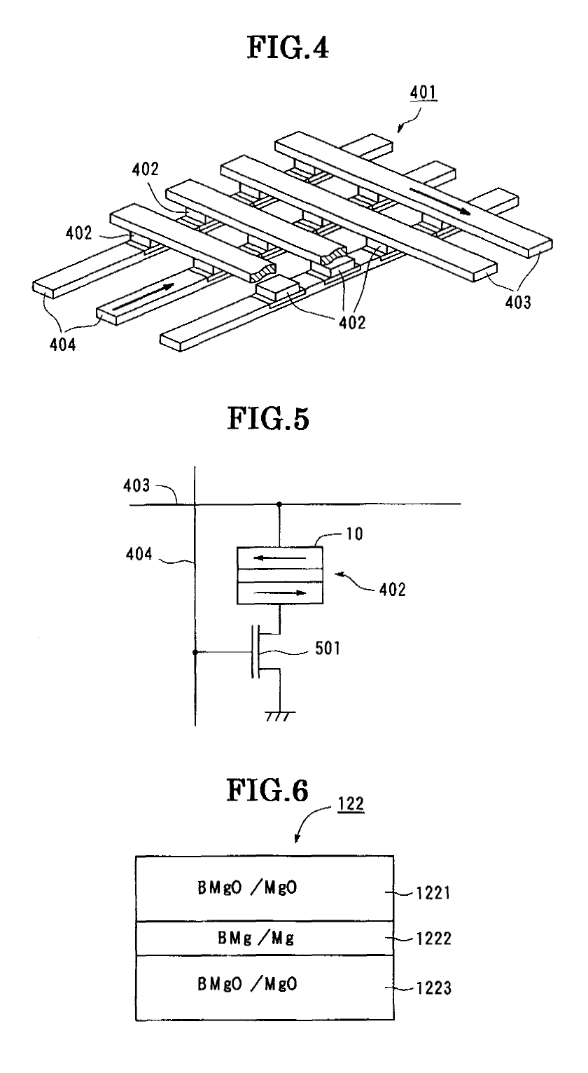

FIG. 4 is a diagram schematically illustrating an MRAM 401 using the magnetoresistance element according to an exemplary embodiment of the invention as a memory element. In the MRAM 401, reference numeral 402 denotes a memory element according to an exemplary embodiment of the invention, reference numeral 403 denotes a word line, and reference numeral 404 denotes a bit line. A plurality of memory elements 402 are arranged at intersections of a plurality of word lines 403 and a plurality of bit lines 404 in a lattice shape. Each of the plurality of memory elements 402 may store 1-bit information.

FIG. 5 is an equivalent circuit diagram of a TMR element 10 that stores 1-bit information and a transistor 501 having a switching function, which are provided at the intersection of the word line 403 and the bit line 404 in the MRAM 401.

### Examples

The magnetoresistance element shown in FIG. 1 was manufactured by the film forming apparatus shown in FIG. 2. The deposition conditions of the TMR element 12, which was the main component, were as follows.

The CoFeB layer 121 was formed using a target with a CoFeB composition ratio (atomic:atom ratio) of 60/20/20 at an Ar gas (sputtering gas) pressure of 0.03 Pa. The CoFeB layer 121 was formed by a magnetron DC sputtering (chamber 201A) at a sputtering rate of 0.64 nm/sec. In this case, the CoFeB layer 121 had an amorphous structure.

Then, the sputtering apparatus was replaced with another sputtering apparatus (chamber 2018), and a target with a MgO composition ratio (atomic:atom ratio) of 50/50 was used. The tunnel barrier layer 122, which was the Mg oxide layer as the sixth layer, was formed by magnetron RF sputtering (13.56 MHz) at an Ar gas (sputtering gas) pressure of 0.2 Pa in the preferable range of 0.01 Pa to 0.4 Pa. In this case, the Mg oxide layer (tunnel barrier layer 122) had a polycrystalline structure including the aggregate 71 of the columnar crystals 72 shown in FIG. 7. In addition, the deposition rate of the magnetron RF sputtering (13.56 MHz) was 0.14 nm/sec. In this example, the Mg oxide layer was formed at a deposition rate of 0.14 nm/sec. However, the Mg oxide layer may be formed at a deposition rate of 0.01 nm/sec to 1.0 nm/sec.

In this example, after the above-mentioned step, the sputtering apparatus was replaced with another sputtering apparatus (chamber 201C) and a ferromagnetic layer (the CoFeB layer 1232 as the seventh layer, the Ta layer 162 as the eighth layer, and the NiFe layer 1231 as the ninth layer), which was a magnetization free layer, was formed. The CoFeB layer 1232 and the NiFe layer 1231 were formed at an Ar gas (sputtering gas) pressure of 0.03 Pa. The CoFeB layer 1232 and the NiFe layer 1231 were formed by a magnetron DC sputtering (chamber 201A) at a sputtering rate of 0.64 nm/sec. In this case, the CoFeB layer 1232 and the NiFe layer 1231 were formed using a target with a CoFeB composition ratio (atomic) of 25/25/50 and a target with a NiFe composition ratio (atomic) of 40/60, respectively. Immediately after the CoFeB layer 1232 and the NiFe layer 1231 were formed, they had an amorphous structure.

The magnetoresistance element 10 formed by sputtering deposition in each of the film-forming magnetron sputtering chambers 201A to 201C was annealed in a heat treatment furnace in a magnetic field of 8 kOe at a temperature of about 300° C. for 4 hours. As a result, it was found that the amorphous structure of the CoFeB layer 121, the CoFeB layer 1232, and the NiFe layer 1231 was changed into a polycrystalline structure including the aggregate 71 of the columnar crystals 72 shown in FIG. 7.

The annealing step enables the magnetoresistance element 10 to have the TMR effect. In addition, predetermined magnetization was given to the antiferromagnetic layer 14, which was the PtMn layer as the second layer, by the annealing step.

As a comparative example of the invention, a magnetoresistance element was manufactured by the same method as that in the example except that the Ta layer, which was the eighth layer, was omitted and a CoFeB layer (CoFeB composition ratio: 25/25/50) was used instead of the NiFe layer, which was the ninth layer.

The MR ratio of the magnetoresistance element according to the example and the MR ratio of the magnetoresistance element according to the comparative example were measured and compared. As a result, the MR ratio of the magnetoresistance element according to the example was 1.2 to 1.5 times more than the MR ratio of the magnetoresistance element according to the comparative example.

The MR ratio is a parameter related to the magnetoresistive effect in which, when the magnetization direction of a magnetic film or a magnetic multi-layer film varies in response to an external magnetic field, the electric resistance of the film is also changed. The rate of change of the electric resistance is used as the rate of change of magnetoresistance (MR ratio).

A magnetoresistance element was manufactured by the same method as that in the example except that a CoFe (atomic composition ratio of 50/50) layer was used instead of the CoFeB layer 1232, which was the seventh layer. In this case, the same effects as those in the example were obtained.

As a comparative example, a magnetoresistance element was manufactured by the same method as that in the example except that a CoFe (atomic composition ratio of 50/50) layer was used instead of the CoFeB layer 121, which was the magnetization fixed layer, and the MR ratio of the magnetoresistance element was measured. As a result, the MR ratio was 1/100 or less of the MR ratio of the magnetoresistance element according to the example.

A magnetoresistance element was manufactured by the same method as that in the example except that a polycrystalline BMg oxide layer was used as the tunnel barrier layer 122 instead of the polycrystalline Mg oxide layer, and the MR ratio of the magnetoresistance element was measured. A BMg oxide target with a BMgO composition ratio (atomic:atom ratio) of 25/25/50 was used. As a result, the MR ratio was significantly higher than that in the example in which the polycrystalline Mg oxide layer was used (the MR ratio was 1.5 or more times higher than that in the example in which the polycrystalline Mg oxide layer was used).

### DESCRIPTION OF REFERENCE NUMERALS AND SIGNS

10: Magnetoresistance element
11: Substrate
12: TMR element
121: CoFeB ferromagnetic layer (fifth layer)
122: Tunnel barrier layer (sixth layer)
1231: NiFe ferromagnetic layer (ninth layer; magnetization free layer)
1232: CoFe/CoFeB ferromagnetic layer (seventh layer; magnetization free layer)
13: Lower electrode layer (first layer; base layer)
14: Antiferromagnetic layer (second layer)
15: Ferromagnetic layer (third layer)
161: Nonmagnetic layer for exchange coupling (fourth layer)
162: Nonmagnetic intermediate layer (eighth layer)
17: Upper electrode layer (tenth layer)
18: Hard mask layer (eleventh layer)
19: Magnetization fixed layer
200: Magnetoresistance element manufacturing apparatus
201A to 201C: Film forming chamber
202: Transport chamber
203: Etching chamber
204: Gate valve
205, 206: Load lock and unload lock chamber
31 to 35, 41 to 45, 51 to 54: Cathode
207A to 207C: Power supply unit
301: Transport chamber
302 to 304: Film forming chamber
305: Load lock and unload lock chamber
306: Central processing unit (CPU)
307 to 311: Bus line
312: Storage medium
401: MRAM
402: Memory element
403: Word line
404: Bit line
501: Transistor
71: Aggregate of columnar crystals
72: Columnar crystal
81: Mg layer or BMg layer
82: Mg oxide layer or BMg oxide layer
83: Mg layer or BMg layer

1. A magnetoresistance element comprising:
a substrate;
a first crystalline ferromagnetic layer provided on the substrate and made of an alloy containing Co atoms, Fe atoms, and B atoms;
a tunnel barrier layer provided on the first crystalline ferromagnetic layer and including a crystalline boron magnesium oxide layer;
a second crystalline ferromagnetic layer provided on the tunnel barrier layer and made of an alloy containing Co atoms, Fe atoms, and B atoms or an alloy containing Co atoms and Fe atoms;
an intermediate layer provided on the second crystalline ferromagnetic layer and made of a nonmagnetic material; and
a third crystalline ferromagnetic layer provided on the intermediate layer and made of an alloy containing Ni atoms and Fe atoms,
wherein the crystalline boron magnesium oxide layer is represented by the following formula: BₓMg_{y}O_{z}
where x, y, and z satisfy 0.8≦z/(x+y)<1.0.

2. A method of manufacturing a magnetoresistance element, comprising the steps of:
preparing a substrate;
forming a first ferromagnetic layer with an amorphous structure made of an alloy containing Co atoms, Fe atoms, and B atoms on the substrate using a sputtering method;
forming a crystalline boron magnesium oxide layer on the first ferromagnetic layer using the sputtering method;
forming a second ferromagnetic layer with an amorphous structure made of an alloy containing Co atoms, Fe atoms, and B atoms or an alloy containing Co atoms and Fe atoms on the crystalline boron magnesium oxide layer using the sputtering method;
forming a nonmagnetic layer on the second ferromagnetic layer using the sputtering method;
forming a third ferromagnetic layer made of an alloy containing Ni atoms and Fe atoms on the nonmagnetic layer using the sputtering method; and
crystallizing the first and second ferromagnetic layers with the amorphous structure,
wherein the crystalline boron magnesium oxide layer is represented by the following formula: BₓMg_{y}O_{z}
where x, y, and z satisfy 0.8≦z/(x+y)<1.0.

3. A storage medium that stores a control program for manufacturing a magnetoresistance element using the steps of:
preparing a substrate;
forming a first ferromagnetic layer with an amorphous structure made of an alloy containing Co atoms, Fe atoms, and B atoms on the substrate using a sputtering method;
forming a crystalline magnesium oxide layer or a crystalline boron magnesium oxide layer on the first ferromagnetic layer using the sputtering method;
forming a second ferromagnetic layer with an amorphous structure made of an alloy containing Co atoms, Fe atoms, and B atoms or an alloy containing Co atoms and Fe atoms on the crystalline boron magnesium oxide layer using the sputtering method;
forming a nonmagnetic layer on the second ferromagnetic layer using the sputtering method;
forming a third ferromagnetic layer made of an alloy containing Ni atoms and Fe atoms on the nonmagnetic layer using the sputtering method; and
crystallizing the first and second ferromagnetic layers with the amorphous structure,
wherein the crystalline boron magnesium oxide layer is represented by the following formula: BₓMg_{y}O_{z}
where x, y, and z satisfy 0.8≦z/(x+y)<1.0.

4. A method of manufacturing a magnetoresistance element, comprising the steps of:
preparing a substrate;
forming a first ferromagnetic layer with an amorphous structure made of an alloy containing Co atoms, Fe atoms, and B atoms on the substrate using a sputtering method;
forming a layer made of a crystalline boron magnesium alloy on the first ferromagnetic layer using the sputtering method and oxidizing the boron magnesium alloy to form a crystalline boron magnesium oxide layer;
forming a second ferromagnetic layer with an amorphous structure made of an alloy containing Co atoms, Fe atoms, and B atoms or an alloy containing Co atoms and Fe atoms on the crystalline boron magnesium oxide layer using the sputtering method;
forming a nonmagnetic layer on the second ferromagnetic layer using the sputtering method;
forming a third ferromagnetic layer made of an alloy containing Ni atoms and Fe atoms on the nonmagnetic layer using the sputtering method; and
crystallizing the first and second ferromagnetic layers with the amorphous structure,
wherein the crystalline boron magnesium oxide layer is represented by the following formula: BₓMg_{y}O_{z}
where x, y, and z satisfy 0.8≦z/(x+y)<1.0.

5. A storage medium that stores a control program for manufacturing a magnetoresistance element using the steps of:
preparing a substrate;
forming a first ferromagnetic layer with an amorphous structure made of an alloy containing Co atoms, Fe atoms, and B atoms on the substrate using a sputtering method;
forming a layer made of a crystalline boron magnesium alloy on the first ferromagnetic layer using the sputtering method and oxidizing the boron magnesium alloy to form a crystalline boron magnesium oxide layer;
forming a second ferromagnetic layer with an amorphous structure made of an alloy containing Co atoms, Fe atoms, and B atoms or an alloy containing Co atoms and Fe atoms on the crystalline boron magnesium oxide layer using the sputtering method;
forming a nonmagnetic layer on the second ferromagnetic layer using the sputtering method;
forming a third ferromagnetic layer made of an alloy containing Ni atoms and Fe atoms on the nonmagnetic layer using the sputtering method; and
crystallizing the first and second ferromagnetic layers with the amorphous structure,
wherein the crystalline boron magnesium oxide layer is represented by the following formula: BₓMg_{y}O_{z}
where x, y, and z satisfy 0.8≦z/(x+y)<1.0.
